(19) United States
(12) Patent Application Publication
(10) Pub. No.: US 2025/0349371 A1
(43) Pub. Date: Nov. 13, 2025

(54) MEMORY DEVICE PROGRAM OPERATION

(71) Applicant: MICRON TECHNOLOGY, INC., BOISE, ID (US)

(72) Inventors: Hong-Yan Chen, San Jose, CA (US); Ananya Ravikumar, Folsom, CA (US); Srinivasa Anuradha Bulusu, Boise, ID (US); Josephine Hamada, Folsom, CA (US); Ching-Huang Lu, Fremont, CA (US)

(73) Assignee: MICRON TECHNOLOGY, INC., BOISE, ID (US)

(21) Appl. No.: 19/200,832

(22) Filed: May 7, 2025

Related U.S. Application Data
(60) Provisional application No. 63/645,193, filed on May 10, 2024.

(51) Int. Cl. G11C 16/34; G11C 16/10

(52) U.S. Cl. CPC G11C 16/3427; G11C 16/102; G11C 16/3404

(57) ABSTRACT

A memory device includes an array of memory cells, a plurality of access lines, and a controller. The array of memory cells includes a plurality of strings of series-connected memory cells. Each access line is connected to a respective memory cell of each string of series-connected memory cells. The controller is configured to access the array of memory cells to program a selected memory cell of the array of memory cells connected to a first access line of the plurality of access lines. The selected memory cell is within a selected string of the plurality of strings of series-connected memory cells. The controller is further configured to, during a program operation, bias the first access line to a first voltage level and bias remaining access lines of the plurality of access lines to reduce the flow of residue electrons within the selected string to the selected memory cell.

This application claims the benefit of U.S. Provisional Application No. 63/645,193, filed on May 10, 2024, hereby incorporated herein in its entirety by reference.

### TECHNICAL FIELD

The present disclosure relates generally to memory and, in particular, in one or more embodiments, the present disclosure relates to mitigation of an injection type of disturb during programming operations within a memory device.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor may be connected to a source, while each drain select transistor may be connected to a data line, such as column bit line. Variations using more than one select gate between a string of memory cells and the source, and/or between the string of memory cells and the data line, are known.

In programming memory, memory cells might be programmed as what are often termed single-level cells (SLC). SLC may use a single memory cell to represent one digit (e.g., one bit) of data. For example, in SLC, a Vt of 2.5V or higher might indicate a programmed memory cell (e.g., representing a logical 0) while a Vt of −0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

In programming MLC memory, data values are often programmed using more than one pass, e.g., programming one or more digits in each pass. For example, in four-level MLC (typically referred to simply as MLC), a first digit, e.g., a least significant bit (LSB), often referred to as lower page (LP) data, may be programmed to the memory cells in a first pass, thus resulting in two (e.g., first and second) threshold voltage ranges. Subsequently, a second digit, e.g., a most significant bit (MSB), often referred to as upper page (UP) data may be programmed to the memory cells in a second pass, typically moving some portion of those memory cells in the first threshold voltage range into a third threshold voltage range, and moving some portion of those memory cells in the second threshold voltage range into a fourth threshold voltage range. Similarly, eight-level MLC (typically referred to as TLC) may represent a bit pattern of three bits, including a first digit, e.g., a least significant bit (LSB) or lower page (LP) data; a second digit, e.g., upper page (UP) data; and a third digit, e.g., a most significant bit (MSB) or extra page (XP) data. In operating TLC, the LP data may be programmed to the memory cells in a first pass, resulting in two threshold voltage ranges, followed by the UP data and the XP data in a second pass, resulting in eight threshold voltage ranges, commonly referred to as L0, L1, L2, L3, L4, L5, L6, and L7 states. Similarly, sixteen-level MLC (typically referred to as QLC) may represent a bit pattern of four bits, and 32-level MLC (typically referred to as PLC) may represent a bit pattern of five bits.

A read window, which may be referred to as a read window width, refers to a distance (e.g., in voltage) between adjacent Vt distributions at a particular bit error rate (BER). A read window budget (RWB) may refer to a cumulative value of read windows for a group of programmed cells (e.g., one or more pages of cells). For example, TLC memory cells configured to store three bits of data per cell may be programmed to one of eight different Vt distributions, each corresponding to a respective data state. In this example, the RWB may be the cumulative value (e.g., in voltage) of the seven read windows between the eight Vt distributions.

### BRIEF DESCRIPTION OF THE DRAWINGS

FIG. 1 is a simplified block diagram of a memory in communication with a processor as part of an electronic system, according to an embodiment.

FIGS. 2A-2C are schematics of portions of an array of memory cells as could be used in a memory of the type described with reference to FIG. 1.

FIGS. 3A-3C depict a selected string of series-connected memory cells and corresponding channel potential of the memory cells during different stages of a programming operation of a selected memory cell that might result in an injection type of disturb of the selected memory cell.

FIGS. 4A and 4B depict a selected string of series-connected memory cells and corresponding channel potential of the memory cells during different stages of a programming operation of a selected memory cell to mitigate an injection type of disturb of the selected memory cell according to an embodiment.

FIG. 5 depicts a selected string of series-connected memory cells and corresponding channel potential of the memory cells during a programming operation of a selected memory cell to mitigate an injection type of disturb of the selected memory cell according to another embodiment.

FIG. 6 depicts a selected string of series-connected memory cells and corresponding channel potential of the memory cells during a programming operation of a selected memory cell to mitigate an injection type of disturb of the selected memory cell according to another embodiment.

FIG. 7 is a timing diagram generally depicting waveforms of various nodes of an array of memory cells at various stages of a programming operation of a selected memory cell to mitigate an injection type of disturb of the selected memory cell according to another embodiment.

FIG. 8 depicts a selected string of series-connected memory cells and corresponding channel potential of the memory cells during a programming operation of a selected memory cell to mitigate an injection type of disturb of the selected memory cell according to another embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments may be utilized and structural, logical and electrical changes may be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting unless otherwise apparent from the context.

Ranges might be expressed herein as from “about” one particular value, and/or to “about” another particular value. When such a range is expressed, another embodiment might include from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

During a NAND memory (e.g., TLC NAND memory) program operation, an injection type of disturb of a selected memory cell being programmed might affect the threshold voltage of the selected memory cell. The injection type of disturb might be due to residue electrons from previously programmed memory cells, which are inhibited from programming during the programming of the selected memory cell, that flow to the selected memory cell when a program voltage level (e.g., program pulse) is applied to the selected memory cell. This injection type of disturb might be a hot electron threshold voltage disturb of the selected memory cell. The severity of the hot electron threshold voltage disturb might be dependent upon the total number of subblocks being programmed during the programming operation. For example, the hot electron threshold voltage disturb when programming eight subblocks might be more severe than the hot electron threshold voltage disturb when programming four subblocks. This hot electron threshold voltage disturb may negatively affect the threshold voltage of the selected memory cell (e.g., increase the threshold voltage above a desired threshold voltage), thereby reducing a read window budget for a group of programmed memory cells.

Hot electron threshold voltage disturb may be exhibited for a random data pattern for a program block and may be enhanced by a worst case data pattern for a program block. A selected memory cell to be programmed may be connected to a selected word line (e.g., access line) WL_{N}. In this case, a worst case data pattern might include memory cells connected to word lines WL_{N-1} to WL_{N-2} programmed to a higher data state (e.g., L7 state), memory cells connected to word lines WL_{N-3}, WL_{N-4}, WL_{N-5}, etc. programmed to a lower data state (e.g., L0 state) for more than 10 adjacent word lines, and memory cells connected to another group of word lines programmed to the higher data state (e.g., L7 state) adjacent to the at least 10 word lines connected to the memory cells programmed to the lower data state (e.g., L0). Since a worst case hot electron threshold voltage disturb might not occur when all memory cells connected to source side access lines are programed to a higher data state (e.g., L7 state), the main contributor of the hot electron threshold voltage disturb might not be from locally generated electron/hole pairs between word lines WL_{N} and WL_{N-1}. Accordingly, disclosed herein are devices and methods to mitigate hot electron threshold voltage disturb of selected memory cells during programming operations within a memory device, which might improve the read window budget for a group of programmed memory cells.

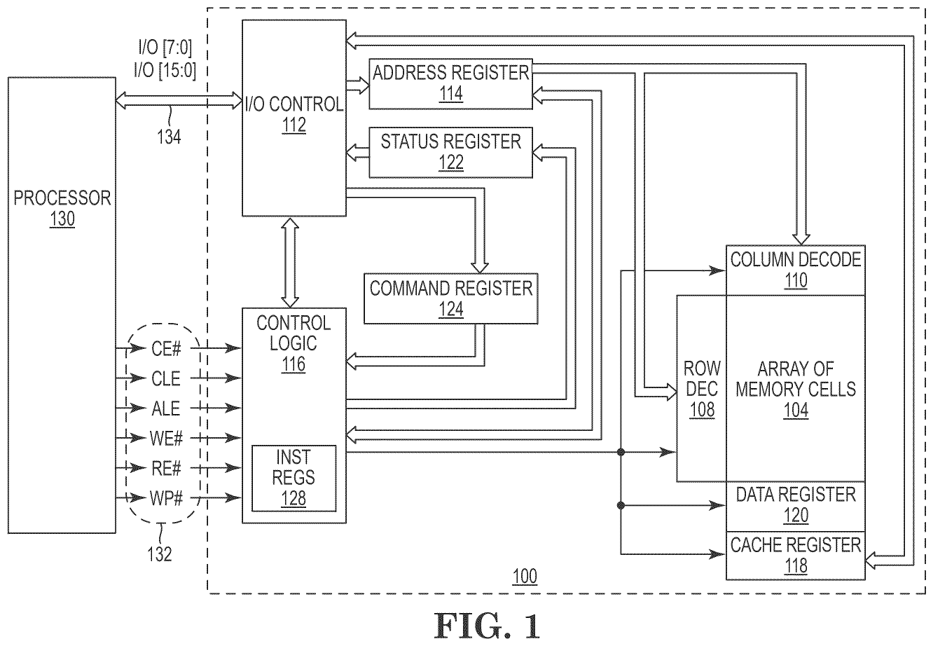

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two target data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands and may generate status information for the external processor 130, i.e., control logic 116 is configured to perform access operations (e.g., sensing operations [which might include read operations and verify operations], programming operations and/or erase operations) on the array of memory cells 104. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104; then new data might be latched in the cache register 118 from the I/O control circuitry 112. During a read operation, data might be passed from the cache register 118 to the I/O control circuitry 112 for output to the external processor 130; then new data might be passed from the data register 120 to the cache register 118. The cache register 118 and/or the data register 120 might form (e.g., might form a portion of) a page buffer of the memory device 100. A page buffer might further include sensing devices (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

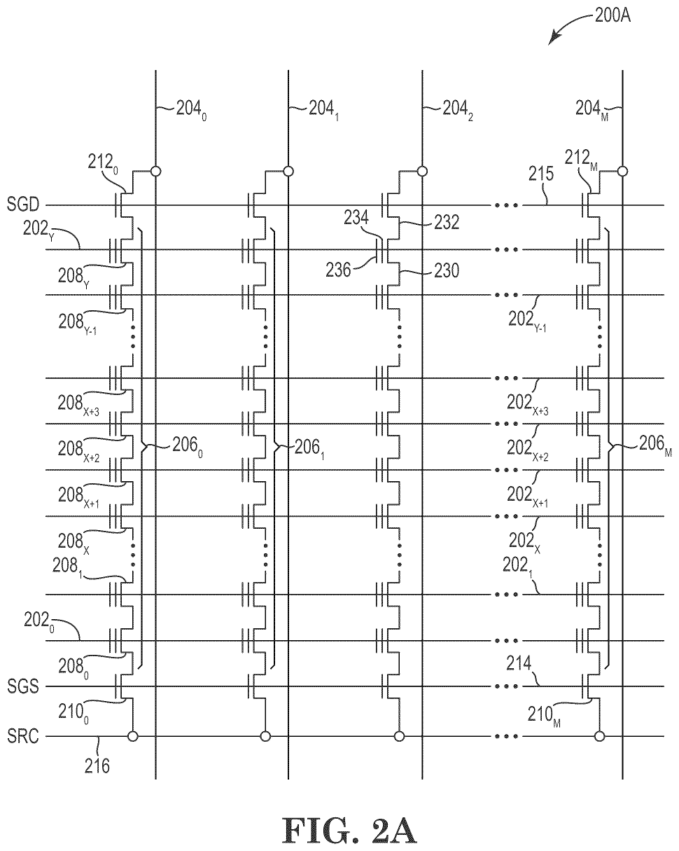

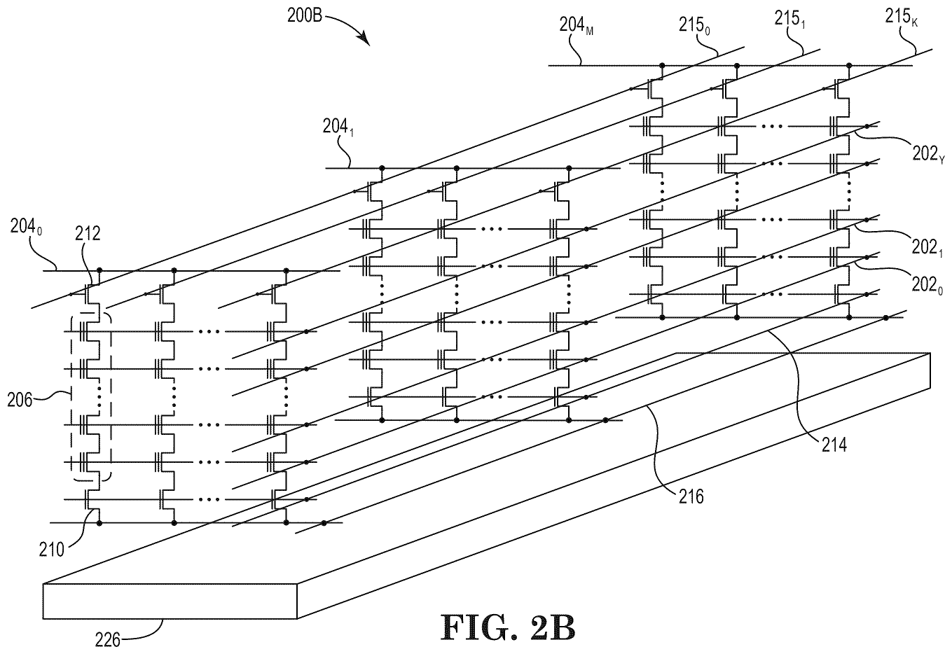

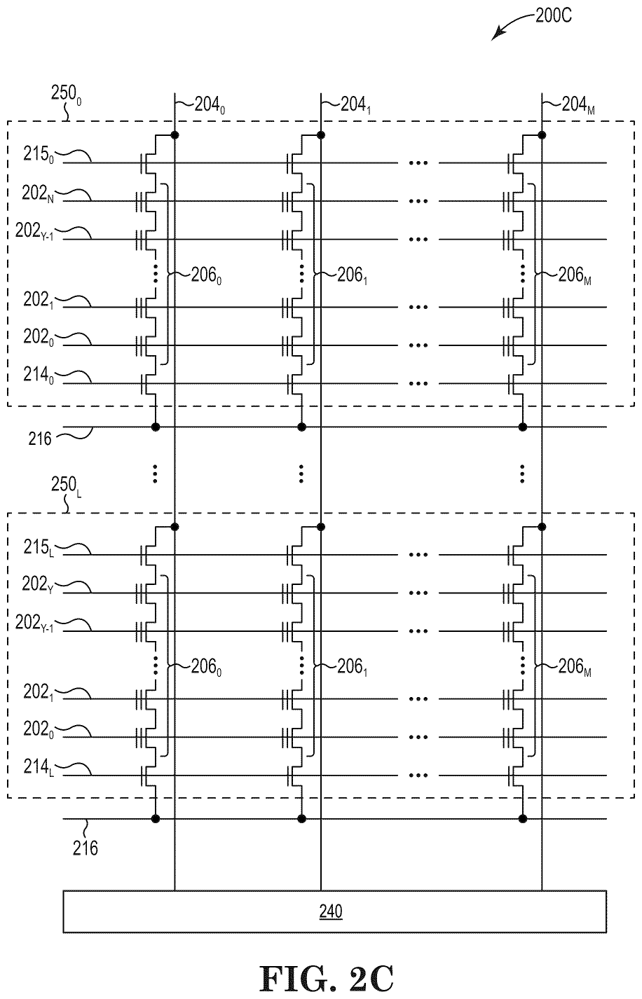

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines (e.g., word lines) 202₀ to 202_{Y}, and data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{Y}. The memory cells 208 might represent non-volatile memory cells for storage of data. The memory cells 208₀ to 208_{Y} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal.

A source of each select gate 210 might be connected to common source 216. The drain of each select gate 210 might be connected to a memory cell 208₀ of the corresponding NAND string 206. For example, the drain of select gate 210₀ might be connected to memory cell 208₀ of the corresponding NAND string 206₀. Therefore, each select gate 210 might be configured to selectively connect a corresponding NAND string 206 to common source 216. A control gate of each select gate 210 might be connected to select line 214.

The drain of each select gate 212 might be connected to the data line 204 for the corresponding NAND string 206. For example, the drain of select gate 212₀ might be connected to the data line 204₀ for the corresponding NAND string 206₀. The source of each select gate 212 might be connected to a memory cell 208_{Y} of the corresponding NAND string 206. For example, the source of select gate 212₀ might be connected to memory cell 208_{Y} of the corresponding NAND string 206₀. Therefore, each select gate 212 might be configured to selectively connect a corresponding NAND string 206 to the corresponding data line 204. A control gate of each select gate 212 might be connected to select line 215.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{Y} and selectively connected to even data lines 204 (e.g., data lines 204₀, 204₂, 204₄, etc.) might be one physical page of memory cells 208 (e.g., even memory cells) while memory cells 208 commonly connected to access line 202_{Y} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{Y} (e.g., all NAND strings 206 sharing common access lines 202). Unless expressly distinguished, a reference to a page of memory cells herein refers to the memory cells of a logical page of memory cells.

Although the example of FIG. 2A is discussed in conjunction with NAND flash, the embodiments and concepts described herein are not limited to a particular array architecture or structure, and can include other structures (e.g., SONOS or other data storage structure configured to store charge) and other architectures (e.g., AND arrays, NOR arrays, etc.).

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B might incorporate vertical structures which might include semiconductor pillars where a portion of a pillar might act as a channel region of the memory cells of NAND strings 206. The NAND strings 206 might be each selectively connected to a data line 204₀ to 204_{M} by a select transistor 212 (e.g., that might be drain select transistors, commonly referred to as select gate drain) and to a common source 216 by a select transistor 210 (e.g., that might be source select transistors, commonly referred to as select gate source). Multiple NAND strings 206 might be selectively connected to the same data line 204. Subsets of NAND strings 206 can be connected to their respective data lines 204 by biasing the select lines 215₀ to 215_{K} to selectively activate particular select transistors 212 each between a NAND string 206 and a data line 204. The select transistors 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel and p-channel transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

FIG. 2C is a further schematic of a portion of an array of memory cells 200C as could be used in a memory of the type described with reference to FIG. 1, e.g., as a portion of array of memory cells 104. Like numbered elements in FIG. 2C correspond to the description as provided with respect to FIG. 2A. Array of memory cells 200C may include strings of series-connected memory cells (e.g., NAND strings) 206, access (e.g., word) lines 202, data (e.g., bit) lines 204, select lines 214 (e.g., source select lines), select lines 215 (e.g., drain select lines) and source 216 as depicted in FIG. 2A. A portion of the array of memory cells 200A may be a portion of the array of memory cells 200C, for example. FIG. 2C depicts groupings of NAND strings 206 into blocks of memory cells 250, e.g., blocks of memory cells 250₀ to 250_{L}. Blocks of memory cells 250 may be groupings of memory cells 208 that may be erased together in a single erase operation, sometimes referred to as erase blocks. Each block of memory cells 250 might include those NAND strings 206 commonly associated with a single select line 215, e.g., select line 215₀. The source 216 for the block of memory cells 250₀ might be a same source as the source 216 for the block of memory cells 250_{L}. For example, each block of memory cells 250₀ to 250_{L} might be commonly selectively connected to the source 216. Access lines 202 and select lines 214 and 215 of one block of memory cells 250 may have no direct connection to access lines 202 and select lines 214 and 215, respectively, of any other block of memory cells of the blocks of memory cells 250₀ to 250_{L}.

The data lines 204₀ to 204_{M} may be connected (e.g., selectively connected) to a buffer portion 240, which might be a portion of a data buffer of the memory. The buffer portion 240 might correspond to a memory plane (e.g., the set of blocks of memory cells 250₀ to 250_{L}). The buffer portion 240 might include sense circuits (not shown in FIG. 2C) for sensing data values indicated on respective data lines 204.

While the blocks of memory cells 250 of FIG. 2C depict only one select line 215 per block of memory cells 250, the blocks of memory cells 250 might include those NAND strings 206 commonly associated with more than one select line 215. For example, select line 215₀ of block of memory cells 250₀ might correspond to the select line 215₀ of the memory array 200B of FIG. 2B, and the block of memory cells of the memory array 200C of FIG. 2C might further include those NAND strings 206 associated with select lines 215₁ to 215_{K} of FIG. 2B. In such blocks of memory cells 250 having NAND strings 206 associated with multiple select lines 215, those NAND strings 206 commonly associated with a single select line 215 might be referred to as a sub-block of memory cells. Each such sub-block of memory cells might be selectively connected to the buffer portion 240 responsive to its respective select line 215.

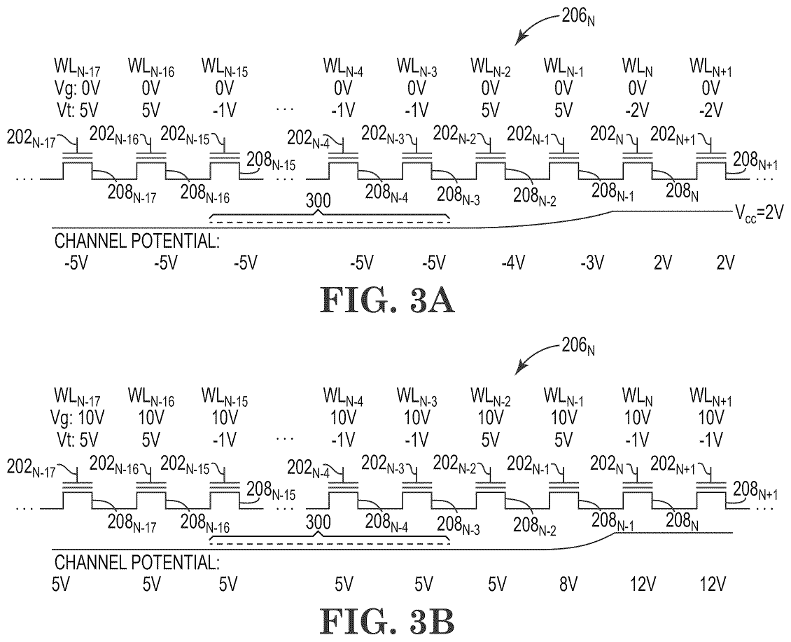

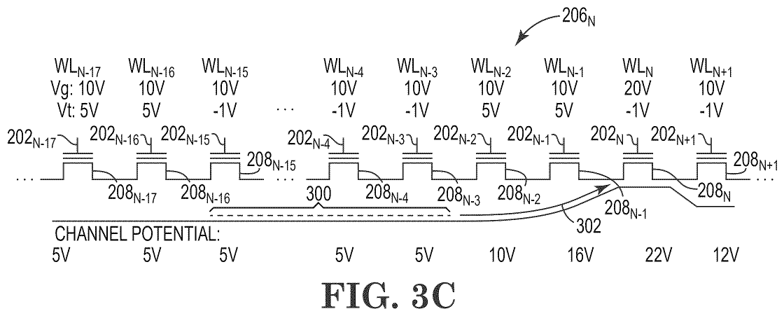

FIGS. 3A-3C depict a selected string 206_{N} of series-connected memory cells and the channel potential (e.g., along a corresponding semiconductor pillar) of the corresponding memory cells 208 during different stages of a programming operation of a selected memory cell 208_{N} that might result in an injection type of disturb (e.g., hot electron threshold voltage disturb) of the selected memory cell 208_{N}. While FIGS. 3A-3C illustrate an example of source to drain programming, where the memory cells are programmed from memory cell 208₀ to memory cell 208_{Y} in the memory arrays 200A-200C of FIGS. 2A-2C, in other examples a similar injection type of disturb might result during drain to source programming, where the memory cells are programmed from memory cell 208_{Y} to memory cell 208₀ in the memory arrays 200A-200C of FIGS. 2A-2C.

FIG. 3A depicts a seeding stage of a programming operation for a selected memory cell 208_{N}. The selected memory cell 208_{N} is a memory cell of a selected string 206_{N} of series-connected memory cells. The selected memory cell 208_{N} is connected to a selected access line 202_{N} (e.g., WL_{N}). String 206_{N} may be any of strings 206₀ to 206_{Y} of a memory array 200A-200C of FIGS. 2A-2C. Memory cells 208_{N-17} to 208_{N+1} may correspond to a portion of memory cells 208₀ to 208_{Y} of the selected string 206_{N}, respectively. Access lines 202_{N-17} to 202_{N+1} (e.g., WL_{N-17} to WL_{N+1}) may correspond to a portion of access lines 202₀ to 202_{Y} connected to the memory cells of the selected string 206_{N}, respectively. In this example, memory cells 208_{N-17}, 208_{N-16}, 208_{N-2}, and 208_{N-1} have been previously programmed to a higher data state (e.g., L7 state) having a higher threshold voltage (e.g., 5 volts), while memory cells 208_{N-15} to 208_{N-3} have been previously programmed to a lower data state (e.g., L0 state) having a lower threshold voltage (e.g., −1 volt). This data pattern might represent a worst case data pattern for the programmed memory cells 208_{N-17} to 208_{N-1}, which may lead to hot electron threshold voltage disturb of the adjacent selected memory cell 208_{N}. In this example, memory cells 208₀ to 208_{N-16} (not shown in FIGS. 3A-3C) have also been previously programmed. The selected memory cell 208_{N}, memory cell 208_{N+1}, and memory cells 208_{N+2} to 208_{Y} (not shown in FIGS. 3A-3C) have not yet been programmed. Therefore, memory cells 208_{N} and 208_{N+1} may have a threshold voltage (e.g., −2 volts) corresponding to an erased memory cell.

The seeding stage may boost the channel potential of the channel region of the memory cells 208 of the selected string 206_{N} by discharging all access lines 202 for the selected string 206_{N} to a reference voltage level (e.g., Vss, ground, or 0 volts) following a program verify operation. During the seeding stage, each access line 202 connected to the selected string 206_{N}, including access lines 202_{N-17} to 202_{N+1}, might be biased to the reference voltage level (e.g., 0 volts) such that the voltage applied to the gate of each memory cell 208 of the selected string 206_{N} including memory cells 208_{N-17} to 208_{N+1} are biased to the reference voltage level. Also during the seeding stage, a supply voltage Vcc (e.g., 2 volts) might be applied to the data line (e.g., 204 of FIGS. 2A-2C) connected to the selected string 206_{N}. Since memory cells 208_{N} and 208_{N+1} to 208_{Y} are not programmed and have a low threshold voltage (e.g., −2 volts), these memory cells are activated (e.g., turned on) and the channel potential of these memory cells is raised to the supply voltage (e.g., 2 volts) as shown in FIG. 3A. Memory cells 208_{N-1} and 208_{N-2}, however, are not activated due to the higher threshold voltages (e.g., 5 volts) of these memory cells resulting in the channel potential dropping (e.g., from 2 volts to −5 volts) between memory cell 208_{N} and memory cell 208_{N-3}. The channel potential remains at the lower voltage (e.g., −5) volts for the remaining programmed memory cells including memory cells 208_{N-17} to 208_{N-3}.

In this example, due to the higher threshold voltages of memory cells 208_{N-16} and 208_{N-2}, residue electrons as indicated at 300 might be trapped between memory cells 208_{N-16} and 208_{N-2} right after a previous program verify operation ends. The residue electrons 300 might be trapped since when a pass voltage level (e.g., 10 volts) applied to the unselected access lines 202_{N-17} to 202_{N-1} during the previous program verify operation ramps down, memory cells 208_{N-16} and 208_{N-2} might be deactivated (e.g., turned off) prior to memory cells 208_{N-15} to 208_{N-3} trapping the residue electrons 300. The residue electrons 300 remain when the seeding stage starts. When the supply voltage Vcc (e.g., 2 volts) is applied to the data line (e.g., 204 of FIGS. 2A-2C) to provide the seeding voltage to the channel of the selected string 206_{N}, the channel potential difference between the source and drain side of the selected string 206_{N} might lead to a drain-induced barrier lowering (DIBL) effect, which might reduce the threshold voltage of memory cell 208_{N-1} and 208_{N-2} to some extent. At this stage, some of the residue electrons 300 might flow to the drain side of the selected string 206_{N} and might be purged, but many of the residue electrons 300 might still remain in the source side of the selected string 206_{N}.

FIG. 3B depicts a pass voltage (Vpass) ramping stage of the programming operation for the selected memory cell 208_{N} of the selected string 206_{N} of series-connected memory cells. During the pass voltage ramping stage, each access line 202 connected to the selected string 206_{N}, including access lines 202_{N-17} to 202_{N+1}, might be biased to a pass voltage level (e.g., 10 volts) such that the voltage applied to the gate of each memory cell 208 of the selected string 206_{N}, including memory cells 208_{N-17} to 208_{N+1}, might be biased to the pass voltage level.

When the pass voltage level ramps up, the entire channel might be boosted to a higher voltage level as shown in FIG. 3B. In one example, where both the source and drain sides of the selected string 206_{N} have the same pass voltage (e.g., 10 volts) as illustrated in FIG. 3B, the channel potential is shifted up by the pass voltage (e.g., 10 volts) along the selected string 206_{N}. In this stage, there might be some source side residue electrons 300 that might flow to the drain side of the selected string 206_{N}. It is noted that in examples where the drain side pass voltage level is higher than the source side pass voltage level, there might be more DIBL effect on memory cells 208_{N-1} and 208_{N-2} that might result in further reduction of the threshold voltages of memory cells 208_{N-1} and 208_{N-2}. In this case, some of the residue electrons 300 might flow to the drain side of the selected string 206_{N} and cause hot electron threshold voltage disturb on the selected memory cell 208_{N}.

FIG. 3C depicts a program voltage (Vpgm) ramping stage of the programming operation for the selected memory cell 208_{N} of the selected string 206_{N} of series-connected memory cells. During the program voltage ramping stage, the selected access line 202_{N} connected to the selected memory cell 208_{N} might be biased to a program voltage level (e.g., 20 volts). Each unselected access line, including access lines 202_{N-17} to 202_{N-1} and 202_{N+1}, connected to the unselected memory cells might remain biased to the pass voltage level (e.g., 10 volts), such that the voltage applied to the gate of each unselected memory cell of the selected string 206_{N}, including memory cells 208_{N-17} to 208_{N-1} and 208_{N+1}, might remain biased to the pass voltage level.

When the program voltage level starts to ramp up, the additional voltage increase (e.g., about 10 volts) on access line 202_{N} quickly increases the memory cell 208_{N} channel potential (e.g., to about 22 volts in this example) resulting in a larger DIBL effect, thereby activating (e.g., turning on) memory cells 208_{N-1} and 208_{N-2}. With memory cells 208_{N-1} and 208_{N-2} activated, most of the residue electrons 300 are now able to flow through to the drain side as indicated at 302, are accelerated by the channel potential gradient between memory cell 208_{N-3} and 208_{N} (e.g., about 17 volts in this example), and are injected into memory cell 208_{N} as high energy carriers. This effect might occur mostly at the beginning of the program pulse, since at a later portion of the program pulse, the channel potential at memory cell 208_{N} might have already decreased due to leakage current from the SGD or locally generated electron/hole pairs at the grain boundaries of the semiconductor (e.g., polysilicon) channel of the memory cells.

The hot electron threshold voltage disturb might be most severe during the program operation when 1) there are a large amount of residue electrons 300 in the source side of the selected string 206_{N}, and 2) most of the residue electrons 300 flow to the drain side at pass voltage ramping and/or program voltage ramping. A worst case data pattern might satisfy both of these criteria. When a large number of lower data state (e.g., L0 state) memory cells are located between groups of higher data state (e.g., L7 state) memory cells on the drain and source side respectively of the lower data state memory cells, residue electrons 300 might be trapped at the end of the program verify stage. The number of higher data state memory cells connected to access lines 202_{N-1} and below determines when these residue electrons can flow to the drain side. If the number of higher data state memory cells is small (e.g., one memory cell), the memory cell 208_{N-1} might easily be activated by DIBL effect, and most of the residue electrons 300 might flow to the drain side during seeding and be purged away. If the number if higher data state memory cells is large (e.g., five or more memory cells), even the large drain side channel potential due to the program voltage pulse might not be sufficient to introduce enough DIBL effect to activate all five higher data state memory cells, thus the hot electron threshold voltage disturb might be less severe.

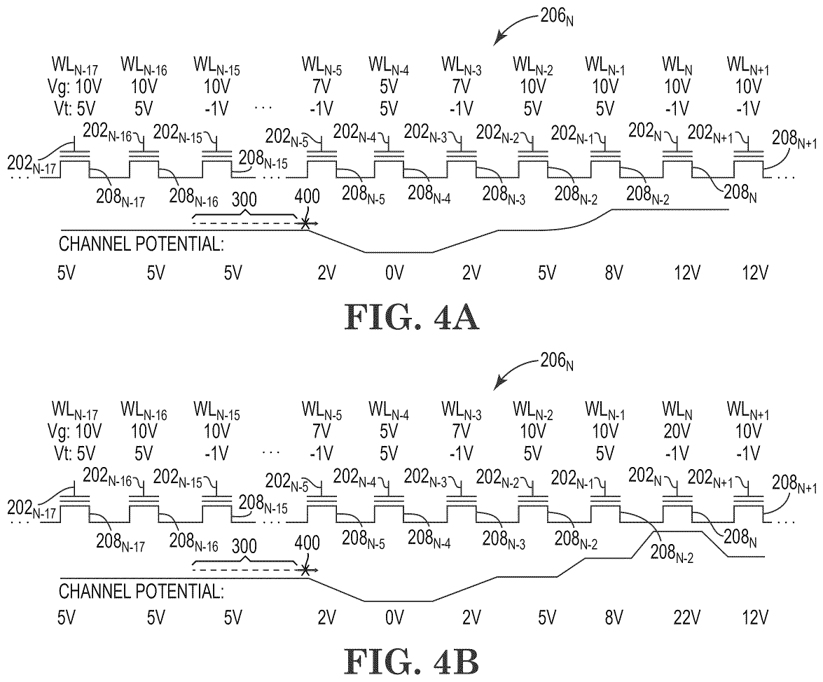

FIGS. 4A and 4B depict a selected string 206_{N} of series-connected memory cells and the channel potential (e.g., along a corresponding semiconductor pillar) of the corresponding memory cells 208 during different stages of a programming operation of a selected memory cell 208_{N} to mitigate the injection type of disturb described with reference to FIGS. 3A-3C according to an embodiment. While FIGS. 4A and 4B illustrate an example of source to drain programming, where the memory cells are programmed from memory cell 208₀ to memory cell 208_{Y} in the memory arrays 200A-200C of FIGS. 2A-2C, in other examples a similar programming operation may also apply to drain to source programming, where the memory cells are programmed from memory cell 208_{Y} to memory cell 208₀ in the memory arrays 200A-200C of FIGS. 2A-2C.

FIG. 4A depicts a pass voltage (Vpass) ramping stage of the programming operation for the selected memory cell 208_{N} of the selected string 206_{N} of series-connected memory cells after a seeding stage of the programming operation for the selected memory cell 208_{N} as previously described with reference to FIG. 3A. As previously described, after the seeding stage, residue electrons 300 might be trapped between memory cells 208_{N-16} and 208_{N-2}. In this example, the residue electrons 300 might be blocked from reaching the selected memory cell 208_{N} by a channel potential barrier. The channel potential barrier might be formed by applying a lower pass voltage level to a selected group of access lines. In this example, a three access line group (e.g., 202_{N-5}, 202_{N-4}, 202_{N-3}) is selected to form the channel potential barrier. A lowest pass voltage level (e.g., 5 volts) might be applied to access line 202_{N-4} to block the residue electrons 300 from flowing to the drain side, while a slightly higher pass voltage level (e.g., 7 volts) might be applied to access lines 202_{N-5} and 202_{N-3} to smooth out the local channel potential gradient to mitigate the potential of local hot electron threshold voltage disturb. The remaining access lines, including access lines 202_{N-17} to 202_{N-6} and 202_{N-2} to 202_{N+1}, might remain biased to the pass voltage level (e.g., 10 volts). Accordingly, due to the channel potential barrier, the residue electrons 300 are blocked as indicated at 400 from flowing to the drain side and hot electron threshold voltage disturb of the selected memory cell 208_{N} is mitigated. By making the channel potential lower via the channel potential barrier, the residue electrons 300 are blocked from leaking to the selected memory cell 208_{N} since the residue electrons 300 can flow to a higher channel potential but not to a lower channel potential.

FIG. 4B depicts a program voltage (Vpgm) ramping stage of the programming operation for the selected memory cell 208_{N} of the selected string 206_{N} of series-connected memory cells. During the program voltage ramping stage, the selected access line 202_{N} connected to the selected memory cell 208_{N} might be biased to the program voltage level (e.g., 20 volts), the voltage levels applied to the three access line group (e.g., 202_{N-5}, 202_{N-4}, 202_{N-3}) forming the channel potential barrier might remain the same (e.g., 7 volts, 5 volts, 7 volts, respectively), and the remaining access lines, including access lines 202_{N-17} to 202_{N-6}, 202_{N-2}, 202_{N-1}, and 202_{N+1}, might remain biased to the pass voltage level (e.g., 10 volts). Accordingly, the channel potential barrier continues to block the residue electrons 300 from reaching the selected memory cell 208_{N} as indicated at 400, thereby mitigating the hot electron threshold voltage disturb of the selected memory cell 208_{N}.

In some examples, a controller (e.g., control logic 116 of FIG. 1) might be configured to control the voltage levels applied to the array of memory cells (e.g., 104, 200A, 200B, 200C) while programming a selected memory cell (e.g., 208_{N}) to reduce the flow of residue electrons 300 within a selected string (e.g., 206_{N}) to the selected memory cell as described with reference to FIG. 4B. The controller might be configured to, during a program operation, apply a first voltage level (e.g., a program voltage level) to a first access line (e.g., a selected access line 202_{N}) to bias the first access line to the first voltage level. The controller might be configured to apply a second voltage level (e.g., a pass voltage level) less than the first voltage level to a second access line (e.g., unselected access line 202_{N-1}) adjacent to the first access line to bias the second access line to the second voltage level. The controller might be configured to apply the second voltage level to a third access line (e.g., unselected access line 202_{N-2}) adjacent to the second access line to bias the third access line to the second voltage level. The controller might be configured to apply a third voltage level (e.g., a lower pass voltage level) less than the second voltage level to a fourth access line (e.g., unselected access line 202_{N-3}) adjacent to the third access line to bias the fourth access line to the third voltage level. The controller might be configured to apply a fourth voltage level (e.g., the lowest pass voltage level) less than the third voltage level to a fifth access line (e.g., unselected access line 202_{N-4}) adjacent to the fourth access line to bias the fifth access line to the fourth voltage level. The controller might be configured to apply the third voltage level to a sixth access line (e.g., unselected access line 202_{N-5}) adjacent to the fifth access line to bias the sixth access line to the third voltage level. The controller might be configured to apply the second voltage level to remaining access lines (e.g., unselected access lines 202_{N-17} to 202_{N-6} and 202_{N+1}) to bias the remaining access lines to the second voltage level.

In some examples, the second voltage level is within a range between about 9 volts and about 11 volts, the third voltage level is within a range between about 6 volts and about 8 volts, and the fourth voltage level is within a range between about 4 volts and about 6 volts. In some examples, the second access line might be directly adjacent to the first access line, the third access line might be directly adjacent to the second access line, the fourth access line might be directly adjacent to the third access line, the fifth access line might be directly adjacent to the fourth access line, and the sixth access line might be directly adjacent to the fifth access line.

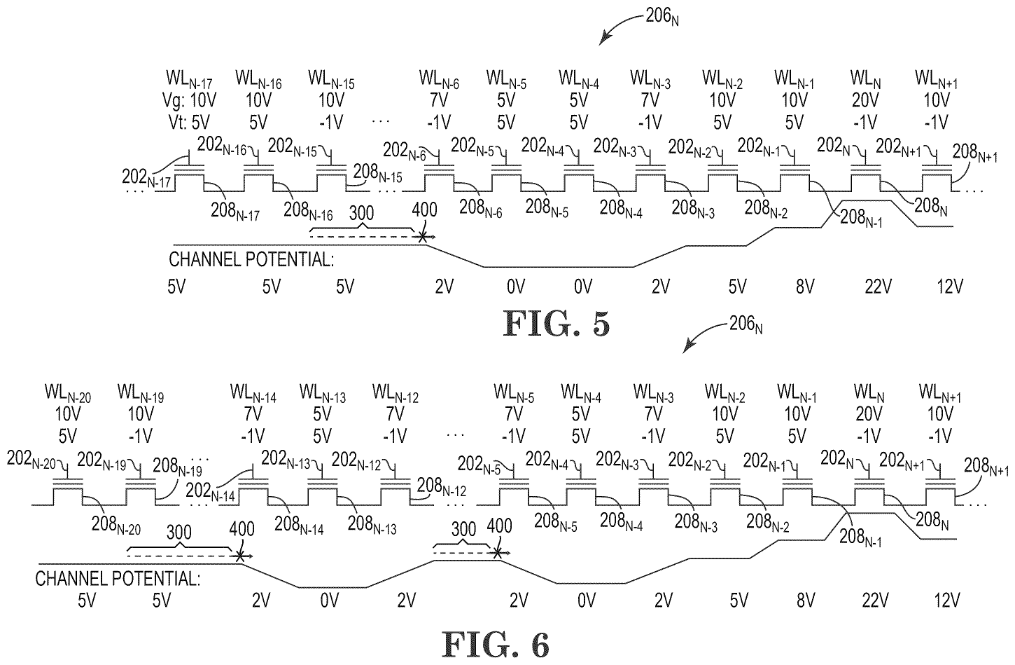

While specific voltage levels are illustrated in FIGS. 4A and 4B (and in FIGS. 5-8 described below) for a reference voltage level, pass voltage levels, and program voltage levels, in other examples the particular voltage levels for the reference voltage level, the pass voltage levels, and the program voltage levels may vary. The pass voltage levels applied to unselected access lines not including the access lines used to form the channel potential barrier may vary between passes of a programming operation to program a selected memory cell to its target data state. The program voltage level applied to the selected access line may also vary between passes of the programming operation to program the selected memory cell to its target data state. In some examples, the lower pass voltage level and the lowest pass voltage level applied to the access lines used to form the channel potential barrier might remain constant between passes of the programming operation to program the selected memory cell to its target data state while the pass voltage levels applied to the other unselected access lines might vary between passes of the programming operation.

FIG. 5 depicts a selected string 206_{N} of series-connected memory cells and the channel potential of the corresponding memory cells 208 during a programming operation of a selected memory cell 208_{N} to mitigate an injection type of disturb of the selected memory cell according to another embodiment. The residue electrons 300 might be blocked as indicated at 400 from reaching memory cell 208_{N} by a channel potential barrier during a pass voltage ramping stage (not shown) and a program voltage ramping stage (shown in FIG. 5). In this example, the channel potential barrier is formed by applying a lower pass voltage level to a selected group of access lines. In this example, a four access line group (e.g., 202_{N-6}, 202_{N-5}, 202_{N-4}, 202_{N-3}) is selected to form the channel potential barrier. The lowest pass voltage level (e.g., 5 volts) might be applied to access lines 202_{N-5} and 202_{N-4} to block the residue electrons 300 from flowing to the drain side, while a slightly higher pass voltage (e.g., 7 volts) might be applied to access lines 202_{N-6} and 202_{N-3} to smooth out the local channel potential gradient to mitigate the potential of local hot electron threshold voltage disturb. During the program voltage ramping stage, the selected access line 202_{N} might be biased to a program voltage level (e.g., 20 volts). The remaining access lines might remain biased to the pass voltage level (e.g., 10 volts). Accordingly, due to the channel potential barrier, the residue electrons 300 are blocked as indicated at 400 from reaching the selected memory cell 208_{N}, thereby mitigating the hot electron threshold voltage disturb of the selected memory cell 208_{N}.

In some examples, a controller (e.g., control logic 116 of FIG. 1) might be configured to control the voltage levels applied to the array of memory cells (e.g., 104, 200A, 200B, 200C) while programming a selected memory cell (e.g., 208_{N}) to reduce the flow of residue electrons 300 within a selected string (e.g., 206_{N}) to the selected memory cell as described with reference to FIG. 5. The controller might be configured to, during a program operation, apply a first voltage level (e.g., a program voltage level) to a first access line (e.g., a selected access line 202_{N}). The controller might be configured to apply a second voltage level (e.g., a pass voltage level) less than the first voltage level to a second access line (e.g., unselected access line 202_{N-1}) adjacent to the first access line. The controller might be configured to apply the second voltage level to a third access line (e.g., unselected access line 202_{N-2}) adjacent to the second access line. The controller might be configured to apply a third voltage level (e.g., a lower pass voltage level) less than the second voltage level to a fourth access line (e.g., unselected access line202_{N-3}) adjacent to the third access line. The controller might be configured to apply a fourth voltage level (e.g., a lowest pass voltage level) less than the third voltage level to a fifth access line (e.g., 202_{N-4}) adjacent to the fourth access line. The controller might be configured to apply the third voltage level to a sixth access line (e.g., unselected access line 202_{N-6}) of the plurality of access lines adjacent to the fifth access line. The controller might be configured to apply the fourth voltage level to a seventh access line (e.g., unselected access line 202_{N-5}) of the plurality of access lines between the fifth access line and the sixth access line. The controller might be configured to apply the second voltage level to remaining access lines (e.g., unselected access lines 202_{N-17} to 202_{N-7} and 202_{N+1}) of the plurality of access lines.

FIG. 6 depicts a selected string 206_{N} of series-connected memory cells and the channel potential of the corresponding memory cells 208 during a programming operation of a selected memory cell 208_{N} to mitigate an injection type of disturb of the selected memory cell according to another embodiment. The residue electrons 300 might be blocked as indicated at 400 from reaching memory cell 208_{N} by more than one channel potential barrier during a pass voltage ramping stage (not shown) and a program voltage ramping stage (shown in FIG. 6). In this example, two channel potential barriers are formed by applying a lower pass voltage to two selected groups of access lines. In this example, a first three access line group (e.g., 202_{N-5}, 202_{N-4}, 202_{N-3}) is selected to form a first channel potential barrier, and a second three access line group (e.g., 202_{N-14}, 202_{N-13}, 202_{N-12}) is selected to form a second channel potential barrier. The lowest pass voltage (e.g., 5 volts) might be applied to access lines 202_{N-4} of the first group and 202_{N-13} of the second group to block the residue electrons 300 from flowing to the drain side, while a slightly higher pass voltage (e.g., 7 volts) might be applied to access lines 202_{N-5} and 202_{N-3} of the first group and to access lines 202_{N-14} and 202_{N-12} of the second group to smooth out the respective local channel potential gradient within each group to mitigate the potential of local hot electron threshold voltage disturb. During the program voltage ramping stage, the selected access line 202_{N} might be biased to a program voltage level (e.g., 20 volts). The remaining access lines might remain biased to the pass voltage level (e.g., 10 volts). Accordingly, due to the channel potential barriers, the residue electrons 300 are blocked as indicated at 400 from reaching the selected memory cell 208_{N}, thereby mitigating the hot electron threshold voltage disturb of the selected memory cell 208_{N}.

In some examples, a controller (e.g., control logic 116 of FIG. 1) might be configured to control the voltage levels applied to the array of memory cells (e.g., 104, 200A, 200B, 200C) while programming a selected memory cell (e.g., 208_{N}) to reduce the flow of residue electrons 300 within a selected string (e.g., 206_{N}) to the selected memory cell as described with reference to FIG. 6. The controller might be configured to, during the program operation, apply the specified voltage levels to a first access line (e.g., 202_{N}), a second access line (e.g., 202_{N-1}), a third access line (e.g., 202_{N-2}), a fourth access line (e.g., 202_{N-3}), a fifth access line (e.g., 202_{N-4}), and a sixth access line (e.g., 202_{N-5}) as previously described and illustrated with reference to FIG. 4B. In addition, the controller might be configured to, during the program operation, apply the third voltage level (e.g., a lower pass voltage level) to a seventh access line (e.g., unselected access line 202_{N-12}). The controller might be configured to apply the fourth voltage level (e.g., the lowest pass voltage level) to an eighth access line (e.g., unselected access line 202_{N-13}) adjacent to the seventh access line. The controller might be configured to apply the third voltage level to a ninth access line (e.g., unselected access line 202_{N-14}) adjacent to the eighth access line. The controller might be configured to apply the second voltage level (e.g., a pass voltage level) to remaining access lines (e.g., unselected access lines 202_{N-20} to 202_{N-15}, 202_{N-11} to 202_{N-6}, and 202_{N+1}).

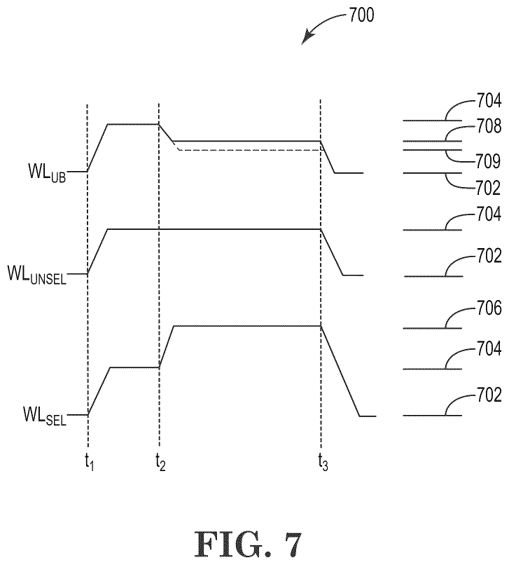

FIG. 7 is a timing diagram 700 generally depicting waveforms of various nodes of an array of memory cells at various stages of a programming operation of a selected memory cell to mitigate an injection type of disturb of the selected memory cell according to another embodiment. Timing diagram 700 might be applicable to drain to source programming operations. In FIG. 7, waveform WL_{SEL} might correspond to the access line (e.g., a selected access line) connected to a memory cell selected for programming during the programming operation, while the waveform WL_{UNSEL} might correspond to a different access line (e.g., an unselected access line) of a string of series-connected memory cells containing the memory cell selected for programming during the programming operation and not connected to a memory cell used to create a channel potential barrier. The waveform WL_{UB} might correspond to a different access line (e.g., an unselected access line) of the string of series-connected memory cells containing the memory cell selected for programming during the programming operation and connected to a previously programmed memory cell to be used to create a channel potential barrier. For example, waveform WL_{SEL} might correspond to access line 202_{N} of FIGS. 4A and 4B, waveform WL_{SEL} might correspond to an access line 202_{N-17} to 202_{N-6}, 202_{N-2}, 202_{N-1}, or 202_{N+1} of FIGS. 4A and 4B, and waveform WL_{UB} might correspond to an access line 202_{N-5}, 202_{N+4}, or 202_{N-3} of FIGS. 4A and 4B. In this example, access lines 202_{N-17} is closer to the SGD, while access line 202_{N+1} is closer to the SGS, such that access lines 202_{N-17} to 202_{N+1} correspond to a portion of access lines 202_{Y} to 202₀, respectively.

Prior to time t₁, the waveforms WL_{SEL}, WL_{UNSEL}, and WL_{UB} might have an initial voltage level 702, such as a reference voltage level, ground, or Vss. The initial voltage level 702 might be applied as part of a seeding stage of the programing operation. At time t₁, the waveforms WL_{SEL}, WL_{UNSEL}, and WL_{UB} might be increased to a voltage level 704. The voltage level 704 might correspond to a pass voltage level (e.g., 10 volts). Between times t₁ and t₂, electrons might flow into the channel on the drain side relative to the selected memory cell since all previously programmed memory cells might be activated due to the voltage level 704. A portion of these electrons might be used to program the selected memory cell between times t₂ and t₃.

At time t₂, the waveform WL_{SEL} might be increased to a voltage level 706. The voltage level 706 might correspond to a program voltage level configured to cause a change (e.g., increase) in a threshold voltage of the memory cell connected to the selected access line and selectively connected to a selected data line receiving an enable voltage. Also at time t₂, the waveform WL_{UB} might be decreased to a voltage level 708 or 709. The voltage level 708 might correspond to a lower pass voltage level (e.g., 7 volts, 6 volts, etc.) and the voltage level 709 might correspond to a lowest pass voltage level (e.g., 5 volts, 4 volts, 3 volts, etc.) configured to form a channel potential barrier as previously described and illustrated with reference to FIGS. 4A and 4B. Between times t₂ and t₃, the residue electrons are blocked from flowing to the selected memory cell due to the channel potential barrier formed due to voltage levels 708 and 709 of the waveform WL_{UB} during the application of the voltage level 706 to the selected access line. In this way, hot electron threshold voltage disturb of the selected memory cell is mitigated. Since sufficient electrons might be provided between times t₁ and t₂, the voltage levels 708 and 709 might be reduced (which might improve efficiency) compared to the voltage levels used to form the channel potential barrier during source to drain programming operations. It is noted that at time t₂, the waveform WL_{SEL} might increase to the voltage level 706 after the waveform WL_{UB} has been decreased to the voltage level 708 or 709. With the programming operation complete at time t₃, the WL_{SEL}, WL_{UNSEL}, and WL_{UB} might be returned to the voltage level 702.

In some examples, a controller (e.g., control logic 116 of FIG. 1) might be configured to control the voltage levels applied to the array of memory cells (e.g., 104, 200A, 200B, 200C) as indicated by timing diagram 700 while programming a selected memory cell (e.g., 208_{N}) to reduce the flow of residue electrons 300 within the selected string (e.g., 206_{N}) to the selected memory cell. The controller might be configured to, during the program operation, apply the specified voltage levels to a first access line (e.g., 202_{N}), a second access line (e.g., 202_{N-1}), a third access line (e.g., 202_{N-2}), a fourth access line (e.g., 202_{N-3}), a fifth access line (e.g., 202_{N-4}), a sixth access line (e.g., 202_{N-5}), and remaining access lines (e.g., 202_{N-17} to 202_{N-6} and 202_{N+1}) as previously described and illustrated with reference to FIG. 4B. In addition, the controller might be configured to, during the program operation, immediately prior to applying the first voltage level to the first access line, the second voltage level to the second access line, the second voltage level to the third access line, the third voltage level to the fourth access line, the fourth voltage level to the fifth access line, the third voltage level to the sixth access line, and the second voltage level to the remaining access lines, apply the second voltage level to each of the plurality of access lines (e.g., 202_{N-17} to 202_{N+1}). In this way, the channel potential barrier to block residue electrons is not formed during the pass stage (e.g., between times t₁ and t₂ of FIG. 7) of the programming operation and is formed during the program stage (e.g., between times t₂ and t₃ of FIG. 7) of the programming operation.

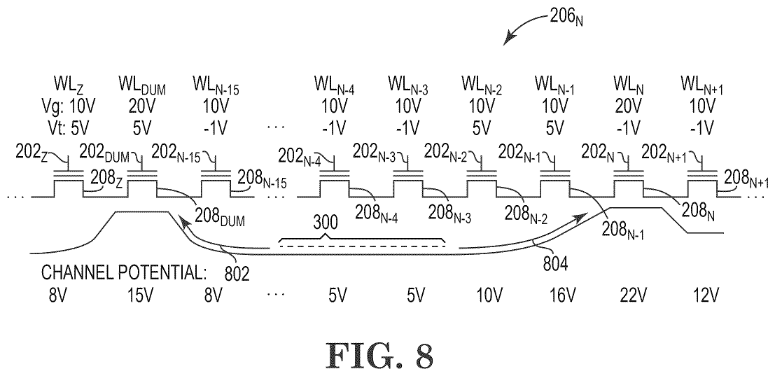

FIG. 8 depicts a selected string 206_{N} of series-connected memory cells and the channel potential of the corresponding memory cells 208 during a programming operation of a selected memory cell 208_{N} to mitigate an injection type of disturb of the selected memory cell according to another embodiment. The selected memory cell 208_{N} is a memory cell of a selected string 206_{N} of series-connected memory cells. The selected memory cell 208_{N} is connected to a selected access line 202_{N} (e.g., WL_{N}). String 206_{N} may be any of strings 206₀ to 206 of a memory array 200A-200C of FIGS. 2A-2C. Memory cells 208_{Z}, 208_{DUM}, 208_{N-15} to 208_{N+1} may correspond to a portion of memory cells 208₀ to 208_{Y} of the selected string 206_{N}, respectively. Access lines 202_{Z}, 202_{DUM}, 202_{N-15} to 202_{N+1} (e.g., WL_{Z}, WL_{DUM}, WL_{N-17} to WL_{N+1}) may correspond to a portion of access lines 202₀ to 202_{Y} connected to the memory cells of the selected string 206_{N}, respectively. In this example, memory cells 208_{Z}, 208_{DUM}, 208_{N-2}, and 208_{N-1} have been previously programmed to a higher data state (e.g., L7 state) having a higher threshold voltage (e.g., 5 volts), while memory cells 208_{N-15} to 208_{N-3} have been previously programmed to a lower data state (e.g., L0 state) having a lower threshold voltage (e.g., −1 volt). This data pattern might represent a worst case data pattern for the programmed memory cells 202_{Z} and 208_{N-15} to 208_{N-1}, which may lead to hot electron threshold voltage disturb of the adjacent selected memory cell 208_{N}. In this example, memory cells 208₀ to 208_{Z-1} (not shown in FIG. 8) have also been previously programmed. The selected memory cell 208_{N}, memory cell 208_{N+1}, and memory cells 208_{N+2} to 208_{Y} (not shown in FIG. 8) have not yet been programmed. Therefore, memory cells 208_{N} and 208_{N+1} may have a threshold voltage (e.g., −1 volt) corresponding to an erased memory cell.

During a program voltage (e.g., Vpgm) ramping stage of the programming operation, the selected access line 202_{N} connected to the selected memory cell 208_{N} might be biased to a program voltage level (e.g., 20 volts), a dummy (e.g., sacrificial) access line 202_{DUM} connected to a dummy memory cell 208_{DUM} might be biased to the program voltage level (e.g., 20 volts), and the remaining access lines, including access lines 202_{Z}, 202_{N-15} to 202_{N-1}, and 202_{N+1}, connected to unselected memory cells might remain biased to a pass voltage level (e.g., 10 volts). In this case, at least a portion of the residue electrons 300 might be directed to the dummy memory cell 208_{DUM} as indicated at 802, which might cause hot electron threshold voltage disturb in the dummy memory cell 208_{DUM}. Some of the residue electrons 300 might also be directed to the selected memory cell 208_{N} as indicated at 804, which might cause hot electron threshold voltage disturb in the selected memory cell 208_{N}. The hot electron threshold voltage disturb of the selected memory cell 208_{N}, however, might be mitigated due to at least a portion of the residue electrons 300 being redirected to the dummy memory cell 208_{DUM}. For source to drain programming operations, the program voltage level is applied to a dummy access line between the selected access line 202_{N} and the SGS (e.g., 214 of FIGS. 2A-2C). For drain to source programming operations, the program voltage level is applied to a dummy access line between the selected access line 202_{N} and the SGD (e.g., 215 of FIGS. 2A-2C). In the embodiment of FIG. 8, no additional bias voltages are used (unlike the two additional bias voltages used in the channel potential barrier embodiments of FIGS. 4A-7) since the program voltage is applied to the dummy access line. The dummy access line might be within a selected number (e.g., 20, 30, 40, etc.) of access lines of the selected access line to redirect at least a portion of the residue electrons away from the selected memory cell during programming operations.

In some examples, a controller (e.g., control logic 116 of FIG. 1) might be configured to control the voltage levels applied to the array of memory cells (e.g., 104, 200A, 200B, 200C) while programming the selected memory cell (e.g., 208_{N}) to reduce the flow of residue electrons 300 within the selected string (e.g., 206_{N}) to the selected memory cell as described with reference to FIG. 8. The controller might be configured to, during a program operation, apply a first voltage level (e.g., a program voltage level) to a first access line (e.g., a selected access line 202_{N}). The controller might be configured to apply the first voltage level to a dummy access line (e.g., dummy access line 202_{DUM}). The controller might be configured to apply a second voltage level (e.g., a pass voltage level) less than the first voltage level to remaining access lines (e.g., unselected access lines 202_{Z}, 202_{N-15} to 202_{N-1}, and 202_{N+1}) of the plurality of access lines.

Applying the first voltage level to the dummy access line might redirect residue electrons within the selected string to the dummy memory cell connected to the dummy access line away from the selected memory cell. Applying the first voltage level to the dummy access line might reduce hot electron threshold voltage disturb of the selected memory cell due to residue electrons within the selected string. The dummy access line might be adjacent to access lines that are connected to programmed memory cells. In some examples, the dummy access line might be within 20 access lines of the selected access line. A memory array might include multiple dummy access lines, such that the dummy access line selected to be biased to the program voltage level to redirect residue electrons away from the selected memory cell might be selected based on its position relative to the selected access line. For example, the dummy access line adjacent to access lines that are connected to programmed memory cells that is closest to the selected access line might be selected.

### CONCLUSION

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

What is claimed is:

1. A memory device comprising:
an array of memory cells comprising a plurality of strings of series-connected memory cells;
a plurality of access lines, each access line of the plurality of access lines connected to a respective memory cell of each string of series-connected memory cells of the plurality of strings of series-connected memory cells; and
a controller configured to access the array of memory cells to program a selected memory cell of the array of memory cells connected to a first access line of the plurality of access lines, the selected memory cell within a selected string of the plurality of strings of series-connected memory cells, wherein the controller is further configured to, during a program operation:
bias the first access line to a first voltage level; and
bias remaining access lines of the plurality of access lines to reduce the flow of residue electrons within the selected string to the selected memory cell.

2. The memory device of claim 1, wherein the controller is further configured to, during the program operation, bias the remaining access lines to reduce hot electron threshold voltage disturb of the selected memory cell.

3. The memory device of claim 1, wherein the controller is further configured to, during the program operation, bias the remaining access lines to:
bias a second access line of the remaining access lines adjacent to the first access line to a second voltage level less than the first voltage level;
bias a third access line of the remaining access lines adjacent to the second access line to the second voltage level;
bias a fourth access line of the remaining access lines adjacent to the third access line to a third voltage level less than the second voltage level;
bias a fifth access line of the remaining access lines adjacent to the fourth access line to a fourth voltage level less than the third voltage level; and
bias a sixth access line of the remaining access lines adjacent to the fifth access line to the third voltage level.

4. The memory device of claim 1, wherein the controller is further configured to, during the program operation, bias the remaining access lines to:
bias a dummy access line of the remaining access lines to the first voltage level; and
bias all other access lines of the remaining access lines to a second voltage level less than the first voltage level.

5. The memory device of claim 1, wherein the array of memory cells comprises a three-dimensional array of NAND memory cells.

6. A memory device comprising:
an array of memory cells comprising a plurality of strings of series-connected memory cells;
a plurality of access lines, each access line of the plurality of access lines connected to a respective memory cell of each string of series-connected memory cells of the plurality of strings of series-connected memory cells; and
a controller configured to access the array of memory cells to program a selected memory cell of the array of memory cells connected to a first access line of the plurality of access lines, the selected memory cell within a selected string of the plurality of strings of series-connected memory cells, wherein the controller is further configured to, during a program operation:
apply a first voltage level to the first access line;
apply a second voltage level less than the first voltage level to a second access line of the plurality of access lines adjacent to the first access line;
apply the second voltage level to a third access line of the plurality of access lines adjacent to the second access line;
apply a third voltage level less than the second voltage level to a fourth access line of the plurality of access lines adjacent to the third access line;
apply a fourth voltage level less than the third voltage level to a fifth access line of the plurality of access lines adjacent to the fourth access line;
apply the third voltage level to a sixth access line of the plurality of access lines adjacent to the fifth access line; and
apply the second voltage level to remaining access lines of the plurality of access lines.

7. The memory device of claim 6, wherein the controller is further configured to, during the program operation, apply the fourth voltage level to a seventh access line of the plurality of access lines between the fifth access line and the sixth access line.

8. The memory device of claim 6, wherein the controller is further configured to, during the program operation:
apply the third voltage level to a seventh access line of the plurality of access lines;
apply the fourth voltage level to an eighth access line of the plurality of access lines adjacent to the seventh access line; and
apply the third voltage level to a ninth access line of the plurality of access lines adjacent to the eighth access line.

9. The memory device of claim 6, wherein the controller is further configured to, during the program operation and immediately prior to applying the first voltage level to the first access line, the second voltage level to the second access line, the second voltage level to the third access line, the third voltage level to the fourth access line, the fourth voltage level to the fifth access line, the third voltage level to the sixth access line, and the second voltage level to the remaining access lines:
apply the second voltage level to each of the plurality of access lines.

10. The memory device of claim 6, wherein the controller is further configured to, during the program operation, apply the third voltage to the fourth access line, apply the fourth voltage level to the fifth access line, and apply the third voltage level to the sixth access line to block residue electrons within the selected string from flowing to the selected memory cell.

11. The memory device of claim 6, wherein the controller is further configured to, during the program operation, apply the third voltage to the fourth access line, apply the fourth voltage level to the fifth access line, and apply the third voltage level to the sixth access line to prevent hot electron threshold voltage disturb of the selected memory cell due to residue electrons within the selected string.

12. The memory device of claim 6, wherein the second access line, the third access line, the fourth access line, and the fifth access line are connected to programmed memory cells of the selected string.

13. The memory device of claim 6, wherein the second voltage level is within a range between 9 and 11 volts, the third voltage level is within a range between 6 and 8 volts, and the fourth voltage level is within a range between 4 and 6 volts.

14. The memory device of claim 6, wherein the second access line is directly adjacent to the first access line, the third access line is directly adjacent to the second access line, the fourth access line is directly adjacent to the third access line, and the fifth access line is directly adjacent to the fourth access line.

15. A memory device comprising:
an array of memory cells comprising a plurality of strings of series-connected memory cells;
a plurality of access lines comprising a dummy access line, each access line of the plurality of access lines connected to a respective memory cell of each string of series-connected memory cells of the plurality of strings of series-connected memory cells; and
a controller configured to access the array of memory cells to program a selected memory cell of the array of memory cells connected to a first access line of the plurality of access lines, the selected memory cell within a selected string of the plurality of strings of series-connected memory cells, wherein the controller is further configured to, during a program operation:
apply a first voltage level to the first access line;
apply the first voltage level to the dummy access line; and
apply a second voltage level less than the first voltage level to remaining access lines of the plurality of access lines.

16. The memory device of claim 15, wherein the controller is further configured to, during the program operation, apply the first voltage level to the dummy access line to redirect residue electrons within the selected string to a dummy memory cell connected to the dummy access line away from the selected memory cell.

17. The memory device of claim 15, wherein the controller is further configured to, during the program operation, apply the first voltage level to the dummy access line to reduce hot electron threshold voltage disturb of the selected memory cell due to residue electrons within the selected string.

18. The memory device of claim 15, wherein the dummy access line is adjacent to access lines of the plurality of access lines that are connected to programmed memory cells.

19. The memory device of claim 15, wherein the dummy access line is within 20 access lines of the selected access line.

20. The memory device of claim 15, wherein the plurality of access lines comprises multiple dummy access lines.
